(19) United States
(12) Patent Application Publication
(10) Pub. No.: US 2026/0362939 A1
(43) Pub. Date: Nov. 12, 2026

(54) DISPLAY DEVICE

(71) Applicants: Rivian IP Holdings, LLC, Irvine, CA (US); Volkswagen Aktiengesellschaft, Wolfsburg (DE)

(72) Inventor: Takayuki SHUTO, Kameyama City, Mie (JP)

(21) Appl. No.: 19/132,040

(22) PCT Filed: Nov. 25, 2022
(86) PCT No.: PCT/JP2022/043436

§ 371 Date: May 22, 2025

(51) Int. Cl. H10K 59/80

(52) U.S. Cl. CPC H10K 59/80515; H10K 59/80521

(57) ABSTRACT

A display device includes light-emitting elements including lower electrodes, a hole transport layer, light-emitting layers, and a first upper electrode layer in this order from a substrate side provided in each of a plurality of subpixels, and the non-emitting charge transfer elements including lower electrodes, the hole transport layer, the light-emitting layers, and a second upper electrode layer in this order from the substrate side provided in each of a plurality of dummy subpixels, and the non-emitting charge transfer elements include a resistance adjustment layer between a first surface of the hole transport layer that is the surface on the light-emitting layers side and a second surface of the second upper electrode layer that is a surface on the side opposite to the substrate, the resistance adjustment layer having a resistivity higher than that of the first upper electrode layer and equal to or lower than 1×10⁹ Ω·cm.

### BACKGROUND ART

In recent years, various display devices including light-emitting elements are developed. Particularly, a display device including an organic light-emitting diode (OLED) or a quantum dot light-emitting diode (QLED) draws a great deal of attention because advantages such as lower power consumption, smaller thickness, and higher picture quality can be achieved.

In the field of these display devices, a charge transfer layer (at least one of a hole injection layer or a hole transport layer, or at least one of an electron injection layer or an electron transport layer) provided between a lower electrode and a light-emitting layer included in a light-emitting element is often formed over the entire surface of a display region.

PTL 1 describes a display device in which each of a hole injection layer and a hole transport layer is formed over the entire surface of a display region as a charge transfer layer provided between a lower electrode and a light-emitting layer included in an OLED.

### CITATION LIST

### Patent Literature

PTL 1: JP 2014-164829 A

### SUMMARY

### Technical Problem

In a case where at least one of a hole injection layer or a hole transport layer is formed over the entire surface of a display region as a charge transfer layer provided between a lower electrode and a light-emitting layer included in a light-emitting element as in the display device described in PTL 1, there is a problem that a bright line appears in an end portion area of the display region.

Such a problem also arises in a case where at least one of an electron injection layer or an electron transport layer is formed over the entire surface of the display region as a charge transfer layer provided between the lower electrode and the light-emitting layer included in the light-emitting element, and a bright line appears in the end portion area of the display region.

An aspect of the disclosure has been contrived in light of the above-mentioned problem, and an object thereof is to provide a display device which prevents, even when a charge transfer layer provided between lower electrodes and a light-emitting layer provided in light-emitting elements is formed over the entire surface of the display region, the phenomenon in which the light-emitting element provided in an end portion area of the display region emits light with luminance higher than intended, causing a bright line to appear.

### Solution to Problem

In order to solve the above-described problem, a display device according to the disclosure includes: a substrate; a display region located on the substrate and provided with a plurality of pixels, each pixel including a plurality of subpixels; a non-display region located on the substrate, the non-display region including a plurality of dummy subpixels provided along an end portion of the display region, the non-display region being continuous from the display region; a plurality of lower electrodes provided in each of the display region and the non-display region; a charge transfer layer which is one continuous layer provided across the display region and the non-display region; a first upper electrode layer provided in the display region; a second upper electrode layer provided in the non-display region; a light-emitting element provided in each of the plurality of subpixels and including the plurality of lower electrodes, the charge transfer layer, a light-emitting layer, and the first upper electrode layer in this order from the substrate side; and a non-emitting charge transfer element provided in each of the plurality of dummy subpixels and including the plurality of lower electrodes, the charge transfer layer, a light-emitting layer, and the second upper electrode layer in this order from the substrate side, in which the non-emitting charge transfer element includes a resistance adjustment layer between a first surface that is a surface of the charge transfer layer on the light-emitting layer side and a second surface of the second upper electrode layer that is the surface on a side opposite to the substrate, the resistance adjustment layer having a resistivity higher than a resistivity of the first upper electrode layer and equal to or lower than 1×10⁹ Ω·cm.

### Advantageous Effects of Disclosure

An aspect of the disclosure has been contrived in light of the above-mentioned problem, and an object thereof is to provide a display device which prevents, even when a charge transfer layer provided between lower electrodes and a light-emitting layer provided in light-emitting elements is formed over the entire surface of the display region, the phenomenon in which the light-emitting element provided in an end portion area of the display region emit light with luminance higher than intended, causing a bright line to appear.

### BRIEF DESCRIPTION OF DRAWINGS

FIG. 1 is a plan view illustrating a schematic configuration of a display device according to a first embodiment.

FIG. 2 is a cross-sectional view illustrating a schematic configuration of a substrate provided in the display device according to the first embodiment illustrated in FIG. 1.

FIG. 3 is a cross-sectional view illustrating a schematic configuration of a light-emitting element provided in a display region and a non-emitting charge transfer element provided in a non-display region of the display device according to the first embodiment.

FIG. 4 is a circuit diagram illustrating a circuit near a boundary between a display region and a non-display region of the display device according to the first embodiment illustrated in FIG. 3.

FIG. 5 is a cross-sectional view illustrating a schematic configuration of a display device according to a comparative example in which a light-emitting element provided around an end portion of a display region emits light with luminance higher than intended, causing a bright line to appear.

FIG. 6 is a circuit diagram for explaining the reason that a bright line appears near the end portion of the display region of the display device according to the comparative example illustrated in FIG. 5.

FIG. 7 is a cross-sectional view illustrating a schematic configuration of a light-emitting element provided in a display region and a non-emitting charge transfer element provided in a non-display region of a display device according to a second embodiment.

FIG. 8 is a cross-sectional view illustrating a schematic configuration of a light-emitting element provided in a display region and a non-emitting charge transfer element provided in a non-display region of a display device according to a third embodiment.

FIG. 9 is a cross-sectional view illustrating a schematic configuration of a light-emitting element provided in a display region and a non-emitting charge transfer element provided in a non-display region of a display device according to a fourth embodiment.

FIG. 10 is a cross-sectional view illustrating a schematic configuration of a light-emitting element provided in a display region and a non-emitting charge transfer element provided in a non-display region of a display device according to a fifth embodiment.

FIG. 11 is a circuit diagram illustrating a circuit near a boundary between a display region and a non-display region of the display device according to the fifth embodiment illustrated in FIG. 10.

FIG. 12 is a cross-sectional view illustrating a schematic configuration of a display device according to another comparative example in which a light-emitting element provided around an end portion of a display region emits light with luminance higher than intended, causing a bright line to appear.

FIG. 13 is a circuit diagram for explaining the reason that a bright line appears near the end portion of the display region of the display device according to another comparative example illustrated in FIG. 12.

FIG. 14 is a cross-sectional view illustrating a schematic configuration of a light-emitting element provided in a display region and a non-emitting charge transfer element provided in a non-display region of a display device according to a sixth embodiment.

FIG. 15 is a cross-sectional view illustrating a schematic configuration of a light-emitting element provided in a display region and a non-emitting charge transfer element provided in a non-display region of a display device according to a seventh embodiment.

FIG. 16 is a cross-sectional view illustrating a schematic configuration of a light-emitting element provided in a display region and a non-emitting charge transfer element provided in a non-display region of a display device according to an eighth embodiment.

FIG. 17 is a plan view illustrating a schematic configuration of a display device according to a ninth embodiment.

### DESCRIPTION OF EMBODIMENTS

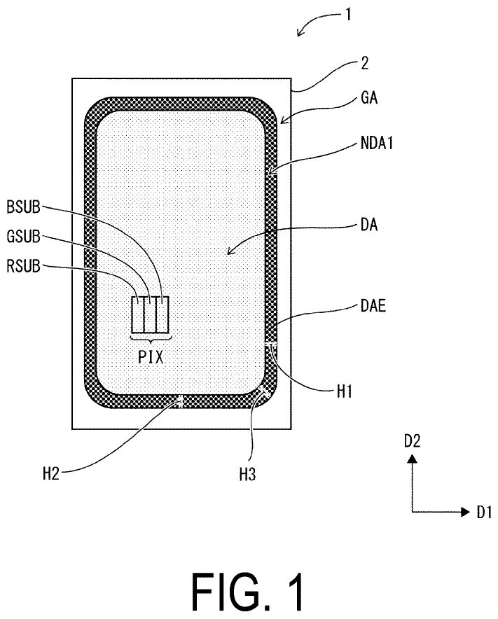

Embodiments of the disclosure will be described with reference to FIGS. 1 to 17 as follows. Hereinafter, for convenience of description, configurations having the same functions as those described in a specific embodiment are denoted by the same reference signs, and descriptions thereof will be omitted.

### First Embodiment

FIG. 1 is a plan view illustrating a schematic configuration of a display device 1 according to a first embodiment.

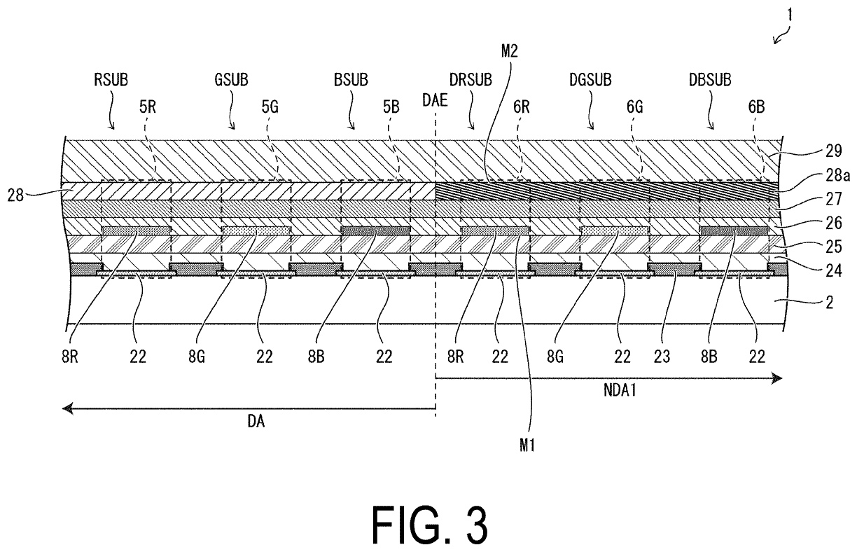

As illustrated in FIG. 1, the display device 1 includes a substrate 2, a display region DA located on the substrate 2 and provided with a plurality of pixels PIX each including a red subpixel RSUB, a green subpixel GSUB and a blue subpixel BSUB, a frame region GA located on the substrate 2 and provided outward from the display region DA, and a non-display region (first non-display region) NDA1, which is located on the substrate 2, is part of the frame region GA and continues from the display region DA, and includes a plurality of dummy subpixels (see FIG. 3) provided along an end portion DAE of the display region DA. Although not illustrated, a terminal portion, a drive circuit, and the like are provided in the frame region GA outside the non-display region NDA1. In the present embodiment, a case will be described as an example in which one pixel PIX includes the red subpixel RSUB, the green subpixel GSUB, and the blue subpixel BSUB. However, the disclosure is not limited thereto, and, for example, one pixel PIX may further include a subpixel of another color in addition to the red subpixel RSUB, green subpixel GSUB, and blue subpixel BSUB.

As illustrated in FIG. 1, since the non-display region NDA1 is included in the frame region GA, it is preferable that the non-display region NDA1 be provided not to be wider than necessary in order to achieve a narrow frame of the display device 1. Therefore, when the shape of the pixel PIX is rectangular as in the present embodiment, it is preferable that the non-display region NDA1 be formed having a width equal to or less than the length of a diagonal line of the pixel PIX. In the present embodiment, a case will be described as an example in which, in order to set the width of the non-display region NDA1 to be equal to or less than the length of the diagonal line of the pixel PIX, a width H1 of a rectangular right-side non-display region and a width H1 of a rectangular left-side non-display region in the non-display region NDA1 illustrated in FIG. 1 are each formed to be a width of the pixel PIX in a first direction D1, a width H2 of a rectangular upper-side non-display region and a width H2 of a rectangular lower-side non-display region in the non-display region NDA1 illustrated in FIG. 1 are each formed to be a width of the pixel PIX in a second direction D2, and widths of four corners of the non-display region NDA1 illustrated in FIG. 1, that is, a width H3 of the deformed portion (upper-right deformed portion) connecting the rectangular upper-side non-display region and the rectangular right-side non-display region, a width H3 of the deformed portion (lower-right deformed portion) connecting the rectangular right-side non-display region and the rectangular lower-side non-display region, a width H3 of the deformed portion (lower-left deformed portion) connecting the rectangular lower-side non-display region and the rectangular left-side non-display region, and a width H3 of the deformed portion (upper-left deformed portion) connecting the rectangular left-side non-display region and the rectangular upper-side non-display region are each formed to be the length of the diagonal line of the pixel PIX; however, the disclosure is not limited thereto. For example, the non-display region NDA1 may be formed to be 50 μm or less in width, or is preferably formed to be 5 μm or more and 50 μm or less in width. By setting the widths of the non-display region NDA1 to be in the above-described range, it is possible to achieve a narrow frame of the display device 1 and to achieve the display device 1 configured to prevent a phenomenon in which the light-emitting element provided in the end portion DAE area of the display region DA emits light with luminance higher than intended and consequently bright lines appear.

In the present embodiment, a case will be described as an example in which the non-display region NDA1 is provided to surround the display region DA, but the disclosure is not limited thereto, and it is sufficient that the non-display region NDA1 is provided to surround at least part of the display region DA. For example, the non-display region NDA1 may be provided to surround only four corners of the display region DA illustrated in FIG. 1, or may be provided to surround at least one of the four sides excluding the four corners of the display region DA illustrated in FIG. 1.

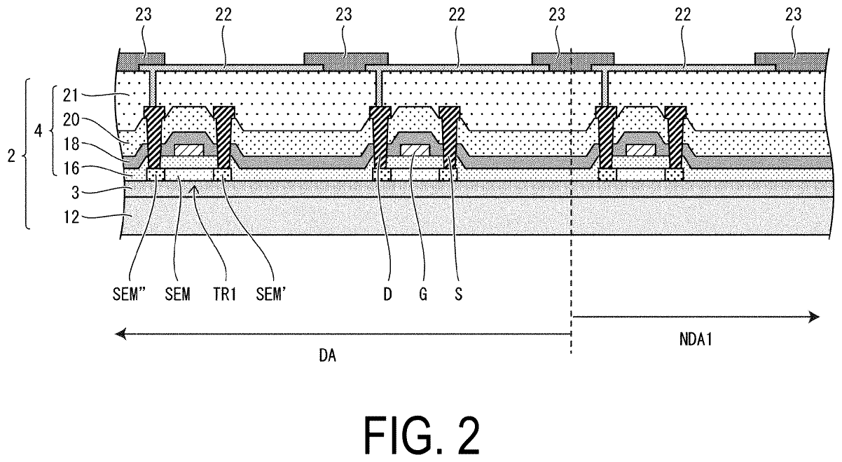

FIG. 2 is a cross-sectional view illustrating a schematic configuration of the substrate 2 provided in the display device 1 illustrated in FIG. 1.

As illustrated in FIG. 2, in the substrate 2 including a transistor TR1 and provided in the display device 1, a barrier layer 3 and a thin film transistor layer 4 including the transistor TR1 are provided on a support substrate 12 in that order from the support substrate 12 side. A lower electrode 22 and an edge cover layer 23 covering an edge portion of the lower electrode 22 are provided on a surface of the substrate 2 including the transistor TR1 in the display region DA and the non-display region NDA1 of the display device 1.

The support substrate 12 may be, for example, a resin substrate made of a resin material such as polyimide, or may be a glass substrate. In the present embodiment, the display device 1 is a flexible display device, and thus a case will be described as an example in which the resin substrate made of the resin material such as polyimide is used as the support substrate 12. However, no such limitation is intended. In a case where the display device 1 is a non-flexible display device, the glass substrate may be used as the support substrate 12.

The barrier layer 3 is a layer that inhibits foreign matters, such as water and oxygen, from entering into the transistor TR1 and the light-emitting element of each color described below. For example, the barrier layer 3 may be constituted of a silicon oxide film, a silicon nitride film or a silicon oxynitride film formed by chemical vapor deposition (CVD), or a layered film thereof.

A transistor TR1 portion in the thin film transistor layer 4 including the transistor TR1 includes a semiconductor film SEM, doped semiconductor films SEM′ and SEM″, an inorganic insulating film 16, a gate electrode G, an inorganic insulating film 18, an inorganic insulating film 20, a source electrode S, a drain electrode D, and a flattening film 21. A portion other than the transistor TR1 portion in the thin film transistor layer 4 including the transistor TR1 includes the inorganic insulating film 16, the inorganic insulating film 18, the inorganic insulating film 20, and the flattening film 21.

The semiconductor films SEM, SEM′ and SEM″ may be formed of low-temperature polysilicon (LTPS) or an oxide semiconductor (for example, an In—Ga—Zn—O based semiconductor), for example. In the present embodiment, a case will be described as an example in which the transistor TR1 has a top gate structure. However, no such limitation is intended, and the transistor TR1 may have a bottom gate structure.

The gate electrode G, the source electrode S, and the drain electrode D may be formed of a single-layer film or a layered film of a metal including, for example, at least one of aluminum, tungsten, molybdenum, tantalum, chromium, titanium, or copper.

The inorganic insulating film 16, the inorganic insulating film 18, and the inorganic insulating film 20 may be composed of, for example, a silicon oxide film, a silicon nitride film or a silicon oxynitride film formed by using, for example, the chemical vapor deposition (CVD) method, or a layered film thereof.

The flattening film 21 can be formed of coatable organic materials such as a polyimide and acrylic material.

The edge cover layer 23 with insulating properties covering the edge of the lower electrode 22 is formed, for example, by applying an organic material such as polyimide or acrylic, and then patterning the organic material by photolithography.

As illustrated in FIG. 2, a control circuit including the transistor TR1 for controlling each of a plurality of the lower electrodes 22 is provided in the thin film transistor layer 4 including the transistor TR1.

FIG. 3 is a cross-sectional view illustrating a schematic configuration of a red light-emitting element 5R, a green light-emitting element 5G and a blue light-emitting element 5B provided in the display region DA, and a non-emitting charge transfer element 6R including a red light-emitting layer 8R, a non-emitting charge transfer element 6G including a green light-emitting layer 8G, and a non-emitting charge transfer element 6B including a blue light-emitting layer 8B provided in the non-display region NDA1 of the display device 1 according to the first embodiment.

As illustrated in FIG. 3, the red subpixel RSUB provided in the display region DA of the display device 1 includes the red light-emitting element 5R including a red light-emitting layer 8R, the green subpixel GSUB provided in the display region DA of the display device 1 includes the green light-emitting element 5G including a green light-emitting layer 8G, and the blue subpixel BSUB provided in the display region DA of the display device 1 includes the blue light-emitting element 5B including a blue light-emitting layer 8B. The red light-emitting element 5R includes the lower electrode 22 as an anode, a hole injection layer 24, a hole transport layer 25, the red light-emitting layer 8R, an electron transport layer 26, an electron injection layer 27, and a first upper electrode layer 28 as a cathode; the green light-emitting element 5G includes the lower electrode 22 as an anode, the hole injection layer 24, the hole transport layer 25, the green light-emitting layer 8G, the electron transport layer 26, the electron injection layer 27, and the first upper electrode layer 28 as a cathode; and the blue light-emitting element 5B includes the lower electrode 22 as an anode, the hole injection layer 24, the hole transport layer 25, the blue light-emitting layer 8B, the electron transport layer 26, the electron injection layer 27, and the first upper electrode layer 28 as a cathode.

In addition, the hole injection layer 24 and the hole transport layer 25 are provided as a charge transfer layer that is one continuous layer provided across the display region DA and the non-display region NDA1, for example, a charge transfer layer (hole transfer layer) which is a common layer formed over the entire surface of the display region DA and non-display region NDA1 between the lower electrode 22 and the red light-emitting layer 8R provided in the red light-emitting element 5R, between the lower electrode 22 and the green light-emitting layer 8G provided in the green light-emitting element 5G, and between the lower electrode 22 and the blue light-emitting layer 8B provided in the blue light-emitting element 5B of the display device 1 illustrated in FIG. 3. In the present embodiment, a case will be described as an example in which both the hole injection layer 24 and the hole transport layer 25 are provided as a charge transfer layer (hole transfer layer) which is a common layer formed over the entire surface of the display region DA and non-display region NDA1, but the disclosure is not limited thereto. Only one of the hole injection layer 24 and the hole transport layer 25 may be provided as a charge transfer layer (hole transfer layer) which is a common layer formed over the entire surface of the display region DA and non-display region NDA1.

Although, in the present embodiment, a case is described as an example in which, in a first dummy subpixel DRSUB provided in the non-display region NDA1 of the display device 1, there is provided the non-emitting charge transfer element 6R having an orderly layered structure in which the lower electrode 22 as an anode, the hole injection layer 24, the hole transport layer 25, the red light-emitting layer 8R, the electron transport layer 26, the electron injection layer 27, and a second upper electrode layer 28a as a cathode are layered on the substrate 2 in that order from the substrate 2 side; in a second dummy subpixel DGSUB provided, there is provided the non-emitting charge transfer element 6G having an orderly layered structure in which the lower electrode 22 as an anode, the hole injection layer 24, the hole transport layer 25, the green light-emitting layer 8G, the electron transport layer 26, the electron injection layer 27, and the second upper electrode layer 28a as a cathode are layered on the substrate 2 in that order from the substrate 2 side; and in a third dummy subpixel DBSUB, there is provided the non-emitting charge transfer element 6B having an orderly layered structure in which the lower electrode 22 as an anode, the hole injection layer 24, the hole transport layer 25, the blue light-emitting layer 8B, the electron transport layer 26, the electron injection layer 27, and the second upper electrode layer 28a as a cathode are layered on the substrate 2 in that order from the substrate 2 side as illustrated in FIG. 3, the disclosure is not limited thereto. For example, the non-display region NDA1 of the display device 1 may be provided with only one or two of the first dummy subpixel DRSUB including the non-emitting charge transfer element 6R having the orderly layered structure, the second dummy subpixel DGSUB including the non-emitting charge transfer element 6G having the orderly layered structure, and the third dummy subpixel DBSUB including the non-emitting charge transfer element 6B having the orderly layered structure. In addition, one of the hole injection layer 24 and the hole transport layer 25 may be omitted in the non-emitting charge transfer elements 6R, 6G, and 6B having the orderly layered structure.

As described above, the charge transfer layer (hole transfer layer) which is one continuous layer provided across the display region DA and the non-display region NDA1 of the display device 1 may be at least one of the hole injection layer 24 or the hole transport layer 25.

In addition, at least one of the electron transport layer 26 or the electron injection layer 27 may be provided between the light-emitting layers 8R, 8G, and 8B and the first upper electrode layer 28 in the display region DA of the display device 1 and between the light-emitting layers 8R, 8G, and 8B and the second upper electrode layer 28a in the non-display region NDA1 of the display device 1, or both the electron transport layer 26 and the electron injection layer 27 may be omitted.

In the present embodiment, the charge transfer layer (hole transfer layer) provided in the display region DA of the display device 1 and the charge transfer layer (hole transfer layer) provided in the non-display region NDA1 of the display device 1 are formed of the same material. That is, when the charge transfer layer (hole transfer layer) provided in the display region DA and the non-display region NDA1 is formed of only the hole injection layer 24, the hole injection layer 24 provided in the display region DA and the hole injection layer 24 provided in the non-display region NDA1 are formed of the same material. When the charge transfer layer (hole transfer layer) provided in the display region DA and the non-display region NDA1 is formed of only the hole transport layer 25, the hole transport layer 25 provided in the display region DA and the hole transport layer 25 provided in the non-display region NDA1 are formed of the same material. When the charge transfer layer (hole transfer layer) provided in the display region DA and the non-display region NDA1 is formed of the hole injection layer 24 and the hole transport layer 25, the hole injection layer 24 and the hole transport layer 25 provided in the display region DA are formed of the same materials as the hole injection layer 24 and the hole transport layer 25 provided in the non-display region NDA1.

Without being limited thereto, the charge transfer layer (hole transfer layer) provided in the display region DA of the display device 1 and the charge transfer layer (hole transfer layer) provided in the non-display region NDA1 of the display device 1 may be formed of different materials as long as the layers are one continuous layer in which holes can transfer from the display region DA to the non-display region NDA1.

In addition, although, in the present embodiment, a case is described as an example in which the red subpixel RSUB and the first dummy subpixel DRSUB are formed in the same shape, the green subpixel GSUB and the second dummy subpixel DGSUB are formed in the same shape, and the blue subpixel BSUB and the third dummy subpixel DBSUB are formed in the same shape, the disclosure is not limited thereto. For example, the subpixels provided in the display region DA and the dummy subpixels provided in the non-display region NDA1 may have different shapes.

Each of the red light-emitting element 5R, the green light-emitting element 5G, and the blue light-emitting element 5B illustrated in FIG. 3 may be a top-emitting light-emitting element in which the lower electrode 22 serving as an anode is made of an electrode material that reflects visible light, the first upper electrode layer 28 serving as a cathode is made of an electrode material that transmits visible light, and light is emitted from the side of the first upper electrode layer 28 located at the upper side, or may be a bottom-emitting light-emitting element in which the lower electrode 22 serving as an anode is made of an electrode material that transmits visible light, the first upper electrode layer 28 serving as a cathode is made of an electrode material that reflects visible light, and light is emitted from the side of the substrate 2 located at the lower side.

When the red light-emitting element 5R, the green light-emitting element 5G, and the blue light-emitting element 5B are top-emitting light-emitting elements, the lower electrodes 22 serving as anodes provided in the non-emitting charge transfer elements 6R, 6G, and 6B illustrated in FIG. 3 may be formed of an electrode material that reflects visible light, and the second upper electrode layer 28a serving as a cathode may be formed of an electrode material that transmits visible light or reflects visible light as long as the layer is a resistance adjustment layer having a resistivity higher than that of the first upper electrode layer 28 and equal to or lower than 1×10⁹ Ω·cm.

On the other hand, when the red light-emitting element 5R, the green light-emitting element 5G, and the blue light-emitting element 5B are top-emitting light-emitting elements, the lower electrodes 22 serving as anodes provided in the non-emitting charge transfer elements 6R, 6G, and 6B illustrated in FIG. 3 may be formed of an electrode material that transmits visible light, and the second upper electrode layer 28a serving as a cathode may be formed of an electrode material that transmits visible light or reflects visible light as long as the layer is a resistance adjustment layer having a resistivity higher than that of the first upper electrode layer 28 and equal to or lower than 1×10⁹ Ω·cm.

The electrode material that reflects visible light is not particularly limited as long as the material can reflect visible light and has electrical conductivity. Examples thereof include metal materials such as Al, Mg, Li and Ag, alloys of these metal materials, a layered body of the above metal materials and transparent metal oxides (for example, indium tin oxide, indium zinc oxide, and indium gallium zinc oxide), and a layered body of the alloys and the transparent metal oxides.

On the other hand, the electrode material that transmits visible light is not particularly limited as long as the material can transmit visible light and has electrical conductivity. Examples include a thin film formed of a transparent metal oxide (for example, indium tin oxide, indium zinc oxide, indium gallium zinc oxide, and the like) or a metal material, such as Al, Mg, Li, and Ag.

In order to realize a display device having a top-emitting light-emitting element, a case in which an electrode material that reflects visible light in which Ag and a transparent metal oxide (e.g., indium tin oxide) are layered from the substrate 2 side in this order is used as the lower electrodes 22 serving as anodes, an Al thin film (resistivity p: 2.65×10⁻⁸ Ω·cm) is used as the first upper electrode layer 28 serving as a cathode, and a Ti film (resistivity p: 4.20×10⁻⁷ Ω·cm) is used as the second upper electrode layer 28a serving as a cathode has been exemplified in the display device 1 of the present embodiment illustrated in FIG. 3; however, the disclosure is not limited thereto. For example, an Ag thin film (resistivity p: 1.59×10⁻⁸ Ω·cm) or an Mg thin film (resistivity p: 4.42×10⁻⁸ Ω·cm) may be used as the first upper electrode layer 28 serving as a cathode, and a Cr film (resistivity p: 1.29×10⁻⁷ Ω·cm) or an Ni film (resistivity p: 6.99×10⁻⁸ Ω·cm) may be used as the second upper electrode layer 28a serving as a cathode.

Since the resistivity of the resistance adjustment layer described above may be higher than that of the first upper electrode layer 28 and 1×10⁹ Ω·cm or less, the resistance adjustment layer may be formed of, for example, a semiconductive material (resistivity p: 1×10⁵ Ω·cm or more and 1×10⁹ Ω·cm or less). Although examples of the semiconductive material include a polymer material including a conductive agent in such an amount that the resistivity is 1×10⁵ Ω·cm or more and 1×10⁹ Ω·cm or less, the disclosure is not limited thereto.

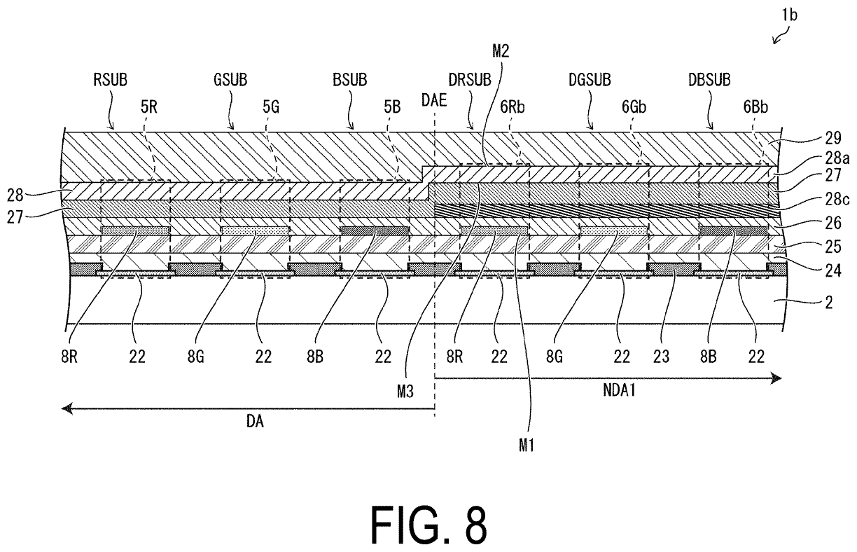

As an example of a case for the display device 1 of the present embodiment illustrated in FIG. 3, in which the non-emitting charge transfer elements 6R, 6G, and 6B include a resistance adjustment layer between a first surface M1, which is the surface of the charge transfer layer (hole transfer layer), for example, the hole transport layer 25 on the light-emitting layers 8R, 8G, and 8B side, and a second surface M2, which is the surface of the second upper electrode layer 28a on the side opposite to the substrate 2, the resistance adjustment layer having a resistivity higher than that of the first upper electrode layer 28 and equal to or lower than 1×10⁹ Ω·cm, an example in which the first upper electrode layer 28 is electrically connected to the second upper electrode layer 28a and the second upper electrode layer 28a is a resistance adjustment layer having a resistivity higher than that of the first upper electrode layer 28 and equal to or lower than 1×10⁹ Ω·cm is described; however the disclosure is not limited thereto. For example, as in the third embodiment to be described below (see FIG. 8), the first and second upper electrode layers 28 and 28a may be one continuous layer formed of the same material, and a resistance adjustment layer 28c may be provided between the first surface M1 of the hole transport layer 25 on the light-emitting layers 8R, 8G, and 8B side and a third surface M3 of the second upper electrode layer 28a on the light-emitting layers 8R, 8G, and 8B side, the resistance adjustment layer having a resistivity higher than that of the first upper electrode layer 28 and equal to or lower than 1×10⁹ Ω·cm.

A material to be used for the hole injection layer 24 is not particularly limited as long as the material is a hole injection material capable of stabilizing the injection of holes into the red light-emitting layer 8R, the green light-emitting layer 8G, and the blue light-emitting layer 8B. For example, PEDOT may be cited as an example, but the disclosure is not limited thereto.

A material to be used for the hole transport layer 25 is not particularly limited as long as the material is a hole transport material capable of transporting holes injected from the lower electrode 22 serving as an anode into the red light-emitting layer 8R, the green light-emitting layer 8G, and the blue light-emitting layer 8B. Among these, a hole transport material having high hole mobility is preferable. For example, TFB (ADS) may be cited as an example, but the disclosure is not limited thereto.

A material to be used for the electron transport layer 26 is not particularly limited as long as the material is an electron transport material capable of transporting electrons injected from the first upper electrode layer 28 or the second upper electrode layer 28a serving as cathodes into the red light-emitting layer 8R, the green light-emitting layer 8G, and the blue light-emitting layer 8B. Among these, the electron transport material having high electron mobility is preferable. For example, ZnMgO may be cited as an example, but the disclosure is not limited thereto.

A material to be used for the electron injection layer 27 is not particularly limited as long as the material is an electron injection material capable of stabilizing the injection of electrons into the red light-emitting layer 8R, the green light-emitting layer 8G, and the blue light-emitting layer 8B. Examples of the electron injection material include alkali metals or alkaline earth metals, oxides of alkali metals or alkaline earth metals, fluorides of alkali metals or alkaline earth metals, and organic complexes of alkali metals, such as aluminum, strontium, calcium, lithium, cesium, magnesium oxide, aluminum oxide, strontium oxide, lithium oxide, lithium fluoride, magnesium fluoride, strontium fluoride, calcium fluoride, barium fluoride, cesium fluoride, and polymethylmethacrylate sodium polystyrene sulfonate.

Note that a sealing layer 29 provided on the first upper electrode layer 28 and the second upper electrode layer 28a is a light-transmitting film, and may be formed of an inorganic sealing film covering the first upper electrode layer 28 and the second upper electrode layer 28a, an organic film serving as an upper layer of the inorganic sealing film, and an inorganic sealing film serving as an upper layer of the organic film, for example. The sealing layer 29 inhibits foreign matters, such as water and oxygen, from entering into the light-emitting element of each color.

As illustrated in FIG. 3, according to the display device 1, holes H⁺ having transferred from the display region DA to the non-display region NDA1 through at least one of the hole injection layer 24 or the hole transport layer 25 as charge transfer layers (hole transfer layers) are accumulated in the non-display region NDA1 having nowhere to go. In the non-emitting charge transfer elements 6R, 6G and 6B provided in the non-display region NDA1, since the second upper electrode layer 28a is provided as a resistance adjustment layer having a resistivity higher than that of the first upper electrode layer 28 and equal to or lower than 1×10⁹ Ω·cm as described above, the holes H⁺ and the electrons e are prevented from recombining in the light-emitting layers 8R, 8G and 8B by lowering the voltage applied between the lower electrodes 22 and the second upper electrode layer 28a, and the holes H⁺ are allowed to flow to the second upper electrode layer 28a, and thus the holes H⁺ accumulated in the non-display region NDA1 can be released. That is, in the non-emitting charge transfer elements 6R, 6G, and 6B, the voltage applied between the lower electrodes 22 and the second upper electrode layer 28a is smaller than the energy required for recombining the holes H⁺ and the electrons e in the light-emitting layers 8R, 8G, and 8B, so light emission can be minimized and the holes H⁺ can flow to the second upper electrode layer 28a. It is possible to prevent the holes H⁺ accumulated as described above from moving toward the second upper electrode layer 28a and accumulating in the non-display region NDA1, and to prevent a bright line from being generated in the non-display region NDA1.

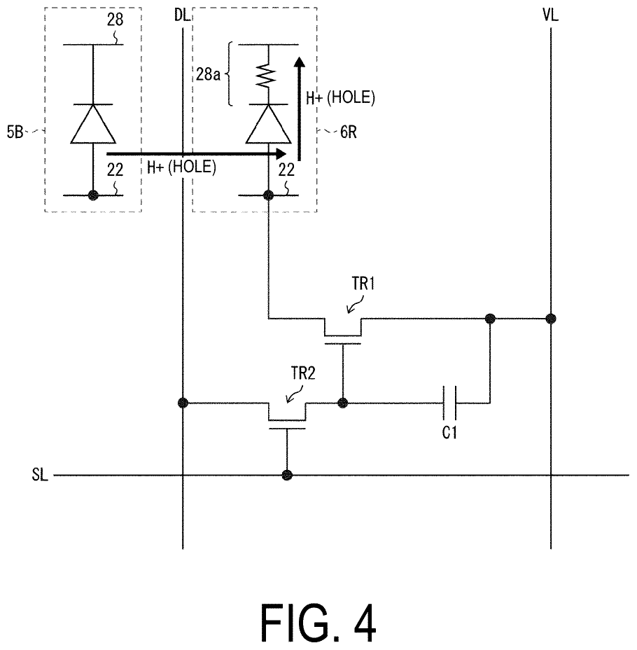

FIG. 4 is a circuit diagram illustrating a circuit near a boundary between the display region DA and the non-display region NDA1 of the display device 1 illustrated in FIG. 3.

FIG. 4 illustrates a schematic circuit configuration of a drive circuit of the blue subpixel BSUB including the blue light-emitting element 5B provided in the display region DA of the display device 1 and a drive circuit of the first dummy subpixel DRSUB including the non-emitting charge transfer element 6R provided in the non-display region NDA1 of the display device 1 adjacent to the blue light-emitting element 5B. The drive circuit of the blue subpixel BSUB including the blue light-emitting element 5B and the drive circuit of the first dummy subpixel DRSUB including the non-emitting charge transfer element 6R are provided on the substrate 2 illustrated in FIG. 3.

As illustrated in FIG. 4, the drive circuit of the first dummy subpixel DRSUB including the non-emitting charge transfer element 6R provided in the non-display region NDA1 of the display device 1 adjacent to the blue light-emitting element 5B includes one non-emitting charge transfer element 6R, two transistors TR1 and TR2, and one holding capacitor C1. Although not illustrated, the drive circuit of the blue subpixel BSUB including the blue light-emitting element 5B provided in the display region DA of the display device 1 has the same configuration as the drive circuit of the first dummy subpixel DRSUB including the non-emitting charge transfer element 6R described above except that the blue light-emitting element 5B is included instead of the non-emitting charge transfer element 6R.

In the drive circuit of the first dummy subpixel DRSUB including the non-emitting charge transfer element 6R illustrated in FIG. 4, the drain electrode of the transistor TR1 serving as a drive transistor is electrically connected to the lower electrode 22 of the non-emitting charge transfer element 6R, the gate electrode of the transistor TR1 is electrically connected to one of the electrodes of the holding capacitor C1 and the drain electrode of the transistor TR2 serving as a selecting transistor, and the source electrode of the transistor TR1 is electrically connected to the other one of the electrodes of the holding capacitor C1 and an ELVDD wiring line VL supplied with a high-level power supply voltage ELVDD from a power source circuit (not illustrated). Although not illustrated, the first upper electrode layer 28 of the blue light-emitting element 5B and the second upper electrode layer 28a that is a resistance adjustment layer of the non-emitting charge transfer elements 6R, 6G, and 6B are electrically connected to an EL VSS wiring line supplied with a low-level power supply voltage EL VSS from a power source circuit. The source electrode of the transistor TR2 serving as a selecting transistor is electrically connected to a data signal line DL supplied with a data signal that is output from a data-side drive circuit (not illustrated), the gate electrode of the transistor TR2 is electrically connected to a scanning signal line SL supplied with a scanning signal that is output from a scanning-side drive circuit (not illustrated), and the drain electrode of the transistor TR2 is electrically connected to the gate electrode of the transistor TR1 and the one of the electrodes of the holding capacitor C1.

In the display device 1 illustrated in FIG. 3 and FIG. 4, in which the hole injection layer 24 and the hole transport layer 25 are provided as a charge transfer layer (hole transfer layer) in the display region DA and the non-display region NDA1, since the non-emitting charge transfer elements 6R, 6G, and 6B are provided in the non-display region NDA1 of the display device 1 as described above, it is possible to minimize the occurrence of bright lines in the end portion area of the display region DA provided near the non-display region NDA1 of the display device 1.

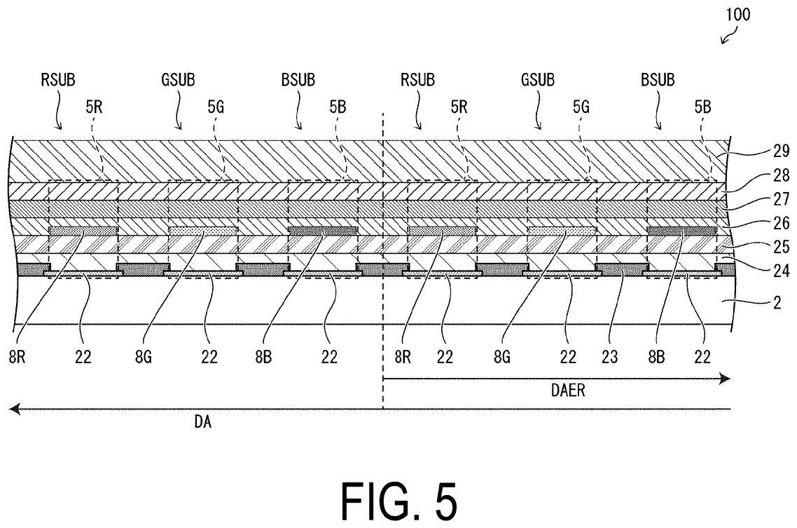

FIG. 5 is a cross-sectional view illustrating a schematic configuration of a display device 100 according to a comparative example in which the red light-emitting element 5R, the green light-emitting element 5G, and the blue light-emitting element 5B provided in an end portion area DAER of the display region DA emit light with luminance higher than intended and consequently bright lines appear.

As illustrated in FIG. 5, the red subpixel RSUB provided in the display region DA including the end portion area DAER of the display region DA in the display device 100 includes the red light-emitting element 5R including the red light-emitting layer 8R, the green subpixel GSUB provided in the display region DA including the end portion area DAER of the display region DA in the display device 100 includes the green light-emitting element 5G including the green light-emitting layer 8G, and the blue subpixel BSUB provided in the display region DA including the end portion area DAER of the display region DA in the display device 100 includes the blue light-emitting element 5B including the blue light-emitting layer 8B. The red light-emitting element 5R includes a lower electrode 22 as an anode, a hole injection layer 24, a hole transport layer 25, the red light-emitting layer 8R, an electron transport layer 26, an electron injection layer 27, and a first upper electrode layer 28 as a cathode; the green light-emitting element 5G includes a lower electrode 22 as an anode, the hole injection layer 24, the hole transport layer 25, the green light-emitting layer 8G, the electron transport layer 26, the electron injection layer 27, and the first upper electrode layer 28 as a cathode; and the blue light-emitting element 5B includes a lower electrode 22 as an anode, the hole injection layer 24, the hole transport layer 25, the blue light-emitting layer 8B, the electron transport layer 26, the electron injection layer 27, and the first upper electrode layer 28 as a cathode.

The hole injection layer 24 and the hole transport layer 25 are provided as a charge transfer layer (hole transfer layer) which is a common layer formed over the entire surface of the display region DA between the lower electrode 22 and the red light-emitting layer 8R provided in the red light-emitting element 5R, between the lower electrode 22 and the green light-emitting layer 8G provided in the green light-emitting element 5G, and between the lower electrode 22 and the blue light-emitting layer 8B provided in the blue light-emitting element 5B of the display device 100 according to the comparative example illustrated in FIG. 5.

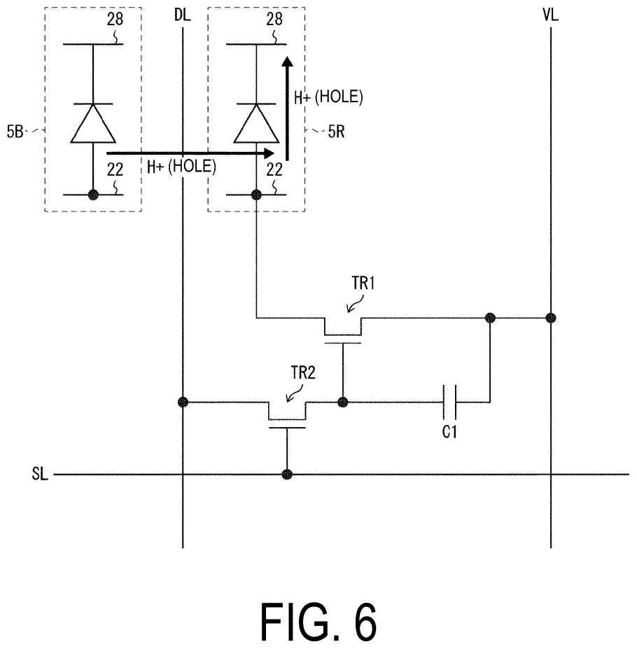

FIG. 6 is a circuit diagram for explaining a reason that a bright line appears in the end portion area DAER of the display region DA of the display device 100 according to the comparative example illustrated in FIG. 5. FIG. 6 illustrates a schematic circuit configuration of a drive circuit of the red subpixel RSUB including the red light-emitting element 5R provided in the end portion area DAER of the display region DA and the blue light-emitting element 5B disposed adjacent to the red light-emitting element 5R, in the display device 100 according to the comparative example illustrated in FIG. 5.

As illustrated in FIG. 6, the drive circuit of the red subpixel RSUB including the red light-emitting element 5R provided in the end portion area DAER of the display region DA in the display device 100 according to the comparative example includes one light-emitting element, two transistors TR1 and TR2, and one holding capacitor C1. The transistor TR1 is a drive transistor and the transistor TR2 is a selecting transistor. Although not illustrated, the drive circuit of the green subpixel GSUB including the green light-emitting element 5G provided in the end portion area DAER of the display region DA in the display device 100 according to the comparative example and the drive circuit of the blue subpixel BSUB including the blue light-emitting element 5B provided in the end portion area DAER of the display region DA in the display device 100 according to the comparative example also have the same configuration as the configuration described above.

In the drive circuit of the red subpixel RSUB including the red light-emitting element 5R illustrated in FIG. 6, the drain electrode of the transistor TR1 serving as a drive transistor is electrically connected to the lower electrode 22 of the red light-emitting element 5R, the gate electrode of the transistor TR1 is electrically connected to one of the electrodes of the holding capacitor C1 and the drain electrode of the transistor TR2 serving as a selecting transistor, and the source electrode of the transistor TR1 is electrically connected to the other one of the electrodes of the holding capacitor C1 and an ELVDD wiring line VL supplied with a high-level power supply voltage ELVDD from a power source circuit (not illustrated). The source electrode of the transistor TR2 serving as a selecting transistor is electrically connected to a data signal line DL supplied with a data signal that is output from a data-side drive circuit (not illustrated), the gate electrode of the transistor TR2 is electrically connected to a scanning signal line SL supplied with a scanning signal that is output from a scanning-side drive circuit (not illustrated), and the drain electrode of the transistor TR2 is electrically connected to the gate electrode of the transistor TR1 and the one of the electrodes of the holding capacitor C1.

In the display device 100 according to the comparative example illustrated in FIG. 5, in which the hole injection layer 24 and the hole transport layer 25 are provided as a charge transfer layer (hole transfer layer) which is a common layer formed over the entire surface of the display region DA, a bright line appears in the end portion area DAER of the display region DA. The inventors of the disclosure consider that one of the reasons for the occurrence of the above-mentioned bright line is as follows. As illustrated in FIG. 5 and FIG. 6, the holes H⁺ having transferred to the end portion area DAER of the display region DA through the hole injection layer 24 and hole transport layer 25 as the charge transfer layer (hole transfer layer) are accumulated in the end portion area DAER of the display region DA having nowhere to go, and in the light-emitting element provided in the end portion area DAER of the display region DA, the holes H⁺ accumulated as described above transfer toward the first upper electrode layer 28 and light is emitted with luminance higher than intended. In the display device 100 according to the comparative example, a case has been described as an example in which the hole injection layer 24 and the hole transport layer 25 are provided as the charge transfer layer (hole transfer layer) which is a common layer formed over the entire surface of the display region DA. However, without being limited thereto, in a case where only one of the hole injection layer 24 and the hole transport layer 25 is provided, a bright line also appears similarly in the end portion area DAER of the display region DA.

### Second Embodiment

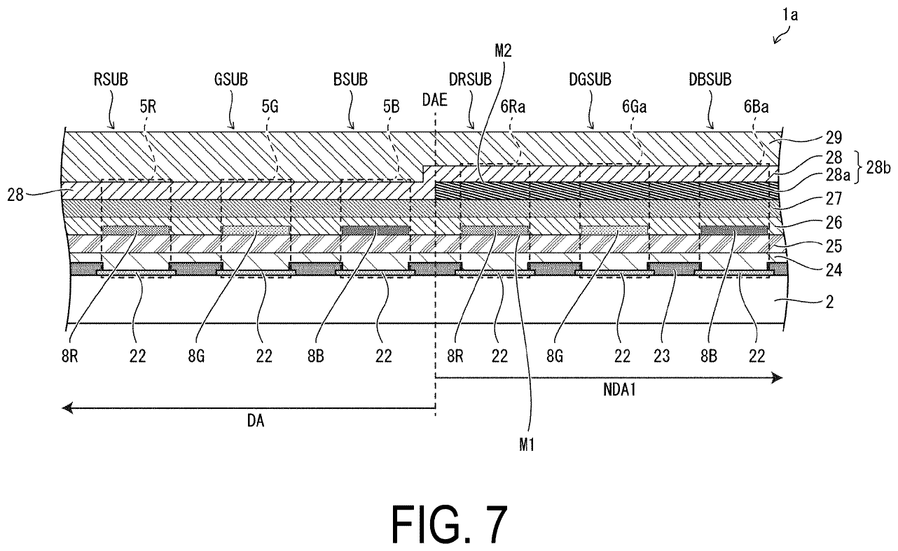

Next, a second embodiment of the disclosure will be described with reference to FIG. 7. A display device 1a of the present embodiment is different from that of the first embodiment in that the first upper electrode layer 28 is also provided in the non-display region NDA1 as one continuous layer, and the second upper electrode layer 28a and the first upper electrode layer 28 are layered in this order from the substrate 2 side in the non-display region NDA1. The other details are as described in the first embodiment. For convenience of description, members having the same functions as those shown in the drawings according to the first embodiment are denoted by the same reference numerals and signs, and descriptions thereof will be omitted.

FIG. 7 is a cross-sectional view illustrating a schematic configuration of a red light-emitting element 5R, a green light-emitting element 5G, and a blue light-emitting element 5B provided in the display region DA, and a non-emitting charge transfer element 6Ra including a red light-emitting layer 8R, a non-emitting charge transfer element 6Ga including a green light-emitting layer 8G, and a non-emitting charge transfer element 6Ba including a blue light-emitting layer 8B provided in the non-display region NDA1 of the display device 1a according to the second embodiment.

As illustrated in FIG. 7, in each of the non-emitting charge transfer element 6Ra including the red light-emitting layer 8R, the non-emitting charge transfer element 6Ga including the green light-emitting layer 8G, and the non-emitting charge transfer element 6Ba including the blue light-emitting layer 8B provided in the non-display region NDA1 of the display device la, the first upper electrode layer 28 is also provided as one continuous layer in the non-display region NDA1, and the second upper electrode layer 28a and the first upper electrode layer 28 are layered in this order from the substrate 2 side to form a layered body 28b in the non-display region NDA1. In such a case, the layered body 28b serves as a cathode.

In the non-emitting charge transfer elements 6Ra, 6Ga and 6Ba provided in the non-display region NDA1, since the second upper electrode layer 28a is provided as a resistance adjustment layer having a resistivity higher than that of the first upper electrode layer 28 and equal to or lower than 1×10⁹ Ω·cm, the holes H⁺ and the electrons e are prevented from recombining in the light-emitting layers 8R, 8G and 8B by lowering the voltage applied between the lower electrodes 22 and the layered body 28b serving as a cathode, and the holes H⁺ are allowed to flow to the layered body 28b serving as a cathode, and thus the holes H⁺ accumulated in the non-display region NDA1 can be released. It is possible to prevent the holes H⁺ accumulated as described above from moving toward the layered body 28b serving as a cathode and accumulating in the non-display region NDA1, and to prevent a bright line from being generated in the non-display region NDA1.

### Third Embodiment

Next, a third embodiment of the disclosure will be described with reference to FIG. 8. A display device 1b of the present embodiment is different from those of the above-described first and second embodiments in that the first upper electrode layer 28 and the second upper electrode layer 28a are one continuous layer made of the same material, and the resistance adjustment layer 28c having a resistivity higher than that of the first upper electrode layer 28 and equal to or lower than 1×10⁹ Ω·cm is provided between the first surface M1 of the hole transport layer 25 serving as a charge transfer layer (hole transfer layer) on the light-emitting layers 8R, 8G and 8B side and the third surface M3 of the second upper electrode layer 28a on the light-emitting layers 8R, 8G and 8B side. The other details are as described in the first and second embodiments. For convenience of description, members having the same functions as those shown in the drawings according to the first and second embodiments are denoted by the same reference numerals and signs, and descriptions thereof will be omitted.

FIG. 8 is a cross-sectional view illustrating a schematic configuration of a red light-emitting element 5R, a green light-emitting element 5G and a blue light-emitting element 5B provided in the display region DA, and a non-emitting charge transfer element 6Rb including a red light-emitting layer 8R, a non-emitting charge transfer element 6Gb including a green light-emitting layer 8G, and a non-emitting charge transfer element 6Bb including a blue light-emitting layer 8B provided in the non-display region NDA1 of the display device 1b according to the third embodiment.

As illustrated in FIG. 8, in each of the non-emitting charge transfer element 6Rb including the red light-emitting layer 8R, the non-emitting charge transfer element 6Gb including the green light-emitting layer 8G, and the non-emitting charge transfer element 6Bb including the blue light-emitting layer 8B provided in the non-display region NDA1 of the display device 1b, the first upper electrode layer 28 and the second upper electrode layer 28a are a continuous layer made of the same material, and the resistance adjustment layer 28c having a resistivity higher than that of the first upper electrode layer 28 and equal to or lower than 1×10⁹ Ω·cm is provided between the first surface M1 of the hole transport layer 25 serving as a charge transfer layer (hole transfer layer) on the light-emitting layers 8R, 8G, and 8B side and the third surface M3 of the second upper electrode layer 28a on the light-emitting layers 8R, 8G, and 8B side.

Although a case in which the resistance adjustment layer 28c is provided between the electron transport layer 26 and the electron injection layer 27 is described as an example in the present embodiment, the disclosure is not limited thereto. For example, the resistance adjustment layer 28c may be provided between the second upper electrode layer 28a and the electron injection layer 27, between the electron transport layer 26 and the light-emitting layers 8R, 8G, and 8B, or between the light-emitting layers 8R, 8G, and 8B and the hole transport layer 25, or may be provided at a plurality of the above-described positions.

In the non-emitting charge transfer elements 6Rb, 6Gb and 6Bb provided in the non-display region NDA1, since the resistance adjustment layer 28c is provided between the first surface M1 of the hole transport layer 25 serving as a charge transfer layer (hole transfer layer) on the light-emitting layers 8R, 8G, and 8B side and the third surface M3 of the second upper electrode layer 28a on the light-emitting layers 8R, 8G, and 8B side, the holes H⁺ and the electrons e are prevented from recombining in the light-emitting layers 8R, 8G and 8B by lowering the voltage applied between the lower electrodes 22 and the second upper electrode layer 28a serving as a cathode, and the holes H⁺ are allowed to flow to the second upper electrode layer 28a serving as a cathode, and thus the holes H⁺ accumulated in the non-display region NDA1 can be released. It is possible to prevent the holes H⁺ accumulated as described above from moving toward the second upper electrode layer 28a serving as a cathode and accumulating in the non-display region NDA1, and to prevent a bright line from being generated in the non-display region NDA1.

### Fourth Embodiment

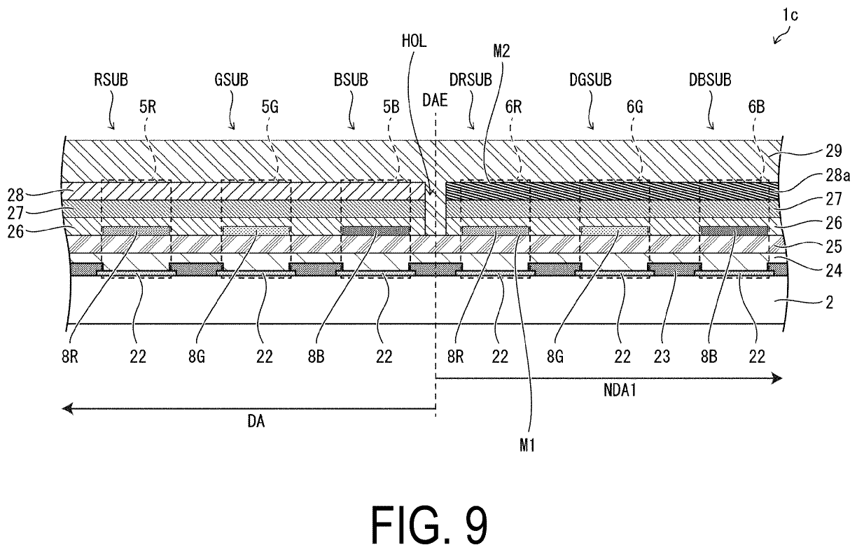

Next, a fourth embodiment of the disclosure will be described with reference to FIG. 9. A display device 1c of the present embodiment is different from those of the first to third embodiments in that the first upper electrode layer 28 and the second upper electrode layer 28a are electrically separated from each other, the second upper electrode layer 28a is a resistance adjustment layer having a resistivity higher than that of the first upper electrode layer 28 and equal to or lower than 1×10⁹ Ω·cm, a first voltage is applied to the first upper electrode layer 28 via a first wiring line, a second voltage is applied to the second upper electrode layer 28a via a second wiring line, and the first voltage and the second voltage are the same. The others are as described in the first to third embodiments. For convenience of description, members having the same functions as those of the members illustrated in the drawings in the first to third embodiments are denoted by the same reference numerals, and descriptions thereof will be omitted.

FIG. 9 is a cross-sectional view illustrating a schematic configuration of a red light-emitting element 5R, a green light-emitting element 5G and a blue light-emitting element 5B provided in the display region DA, and a non-emitting charge transfer element 6R including a red light-emitting layer 8R, a non-emitting charge transfer element 6G including a green light-emitting layer 8G, and a non-emitting charge transfer element 6B including a blue light-emitting layer 8B provided in the non-display region NDA1 of the display device 1c according to the fourth embodiment.

As illustrated in FIG. 9, in the display device 1c, a groove HOL for electrically separating the first upper electrode layer 28 and the second upper electrode layer 28a is provided in an area including an end portion DAE of the display region DA, and the first upper electrode layer 28 and the second upper electrode layer 28a are electrically separated from each other.

Although a case in which the groove HOL is also provided in the electron transport layer 26 and the electron injection layer 27 is described as an example in the present embodiment, the disclosure is not limited thereto, and the groove HOL may be provided only between the first upper electrode layer 28 and the second upper electrode layer 28a.

As illustrated in FIG. 9, in the display device 1c, the first upper electrode layer 28 and the second upper electrode layer 28a are electrically separated from each other, the second upper electrode layer 28a is a resistance adjustment layer having a resistivity higher than that of the first upper electrode layer 28 and equal to or lower than 1×10⁹ Ω·cm, the first voltage is applied to the first upper electrode layer 28 via the first wiring line, the second voltage is applied to the second upper electrode layer 28a via the second wiring line, and the first voltage and the second voltage are the same.

In the display device 1c, the red light-emitting element 5R, the green light-emitting element 5G, and the blue light-emitting element 5B provided in the display region DA can be prevented from being affected by the non-emitting charge transfer elements 6R, 6G, and 6B provided in the non-display region NDA1.

### Fifth Embodiment

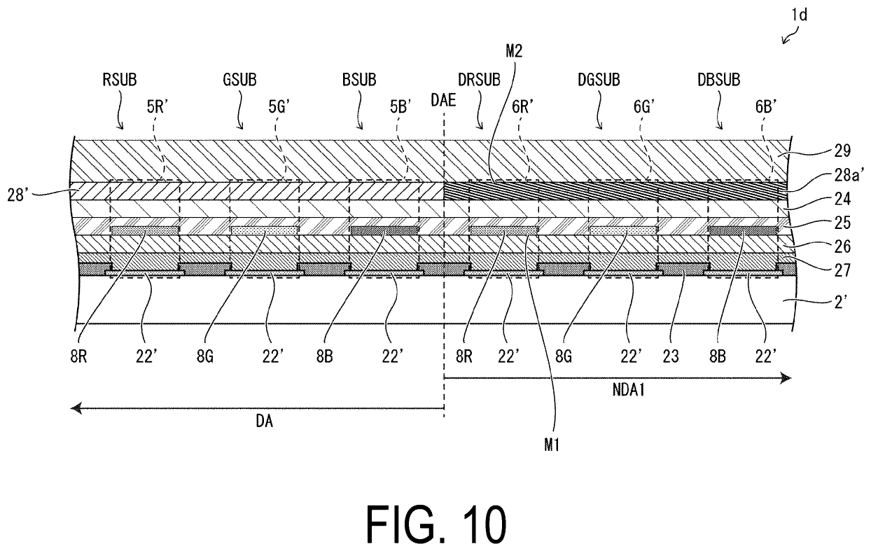

Next, a fifth embodiment of the disclosure will be described with reference to FIGS. 10 to 13. The display device 1d of the present embodiment is different from those of the above-described first to fourth embodiments in that the display region DA includes red light-emitting elements 5R′, green light-emitting elements 5G′, and blue light-emitting elements 5B′ which are light-emitting elements having an inversely layered structure, and the non-display region NDA1 includes non-emitting charge transfer elements 6R′, 6G′, and 6B′ which are non-emitting charge transfer elements having an inversely layered structure. The others are as described in the first to fourth embodiments. For convenience of description, members having the same functions as those of the members illustrated in the drawings in the first to fourth embodiments are denoted by the same reference numerals, and descriptions thereof will be omitted.

FIG. 10 is a cross-sectional view illustrating a schematic configuration of a red light-emitting element 5R′, a green light-emitting element 5G′, and a blue light-emitting element 5B′ that are light-emitting elements having an inversely layered structure provided in the display region DA, and the non-emitting charge transfer element 6R′, 6G′, and 6B′ that are non-emitting charge transfer elements having an inversely layered structure provided in the non-display region NDA1 of the display device 1d according to the fifth embodiment.

In the present embodiment, as illustrated in FIG. 10, a case will be described as an example in which, in a red subpixel RSUB provided in the display region DA of the display device 1d, there is provided the red light-emitting element 5R′ having an inversely layered structure where a lower electrode 22′ as a cathode, an electron injection layer 27, an electron transport layer 26, a red light-emitting layer 8R, a hole transport layer 25, a hole injection layer 24, and a first upper electrode layer 28′ as an anode are layered on a substrate 2′ in that order from the substrate 2′ side; in a green subpixel GSUB, there is provided the green light-emitting element 5G′ having an inversely layered structure where the lower electrode 22′ as a cathode, the electron injection layer 27, the electron transport layer 26, a green light-emitting layer 8G, the hole transport layer 25, the hole injection layer 24, and the first upper electrode layer 28′ serving as an anode are layered on the substrate 2′ in that order from the substrate 2′ side; and in a blue subpixel BSUB, there is provided the blue light-emitting element 5B′ having an inversely layered structure where the lower electrode 22′ as a cathode, the electron injection layer 27, the electron transport layer 26, a blue light-emitting layer 8B, the hole transport layer 25, the hole injection layer 24, and the first upper electrode layer 28′ as an anode are layered on the substrate 2′ in that order from the substrate 2′ side. However, the disclosure is not limited thereto.

In addition, in the present embodiment, as illustrated in FIG. 10, a case will be described as an example in which, in a first dummy subpixel DRSUB provided in the non-display region NDA1 of the display device 1d, there is provided the non-emitting charge transfer element 6R′ having an inversely layered structure where the lower electrode 22′ as a cathode, the electron injection layer 27, the electron transport layer 26, the hole transport layer 25, the hole injection layer 24, and a second upper electrode layer 28a′ as an anode are layered on the substrate 2′ in that order from the substrate 2′ side; in a second dummy subpixel DGSUB, there is provided the non-emitting charge transfer element 6G′ having an inversely layered structure where the lower electrode 22′ as a cathode, the electron injection layer 27, the electron transport layer 26, the hole transport layer 25, the hole injection layer 24, and the second upper electrode layer 28a′ as an anode are layered on the substrate 2′ in that order from the substrate 2′ side; and in a third dummy subpixel DBSUB, there is provided the non-emitting charge transfer element 6B′ having an inversely layered structure where the lower electrode 22′ as a cathode, the electron injection layer 27, the electron transport layer 26, the hole transport layer 25, the hole injection layer 24, and the second upper electrode layer 28a′ as an anode are layered on the substrate 2′ in that order from the substrate 2′ side. However, the disclosure is not limited thereto.

The charge transfer layer (electron transfer layer) which is one continuous layer provided across the display region DA and the non-display region NDA1 of the display device 1d may be at least one of the electron injection layer 27 or the electron transport layer 26.

In addition, at least one of the hole transport layer 25 or the hole injection layer 24 may be provided between the light-emitting layers 8R, 8G, and 8B and the first upper electrode layer 28′ in the display region DA of the display device 1d and between the light-emitting layers 8R, 8G, and 8B and the second upper electrode layer 28a′ in the non-display region NDA1 of the display device 1d, or both the hole transport layer 25 and the hole injection layer 24 may be omitted.

In the present embodiment, the charge transfer layer (electron transfer layer) provided in the display region DA of the display device 1d and the charge transfer layer (electron transfer layer) provided in the non-display region NDA1 of the display device 1d are formed of the same material. That is, when the charge transfer layer (electron transfer layer) provided in the display region DA and the non-display region NDA1 is formed of only the electron injection layer 27, the electron injection layer 27 provided in the display region DA and the electron injection layer 27 provided in the non-display region NDA1 are formed of the same material, when the charge transfer layer (electron transfer layer) provided in the display region DA and the non-display region NDA1 is formed of only the electron transport layer 26, the electron transport layer 26 provided in the display region DA and the electron transport layer 26 provided in the non-display region NDA1 are formed of the same material, and when the charge transfer layer (electron transfer layer) provided in the display region DA and the non-display region NDA1 is formed of the electron injection layer 27 and the electron transport layer 26, the electron injection layer 27 and the electron transport layer 26 provided in the display region DA are formed of the same materials as the electron injection layer 27 and the electron transport layer 26 provided in the non-display region NDA1.

Without being limited thereto, the charge transfer layer (electron transfer layer) provided in the display region DA of the display device 1d and the charge transfer layer (electron transfer layer) provided in the non-display region NDA1 of the display device 1d may be formed of different materials as long as the layers are one continuous layer in which electrons can transfer from the display region DA to the non-display region NDA1.

When the red light-emitting element 5R′, the green light-emitting element 5G′, and the blue light-emitting element 5B′ illustrated in FIG. 10 are top-emitting light-emitting elements, the lower electrodes 22′ serving as cathodes provided in the non-emitting charge transfer elements 6R′, 6G′, and 6B′ illustrated in FIG. 10 may be formed of an electrode material that reflects visible light, and the second upper electrode layer 28a′ serving as an anode may be formed of an electrode material that transmits visible light or reflects visible light as long as the layer is a resistance adjustment layer having a resistivity higher than that of the first upper electrode layer 28′ and equal to or lower than 1×10⁹ Ω·cm.

On the other hand, when the red light-emitting element 5R′, the green light-emitting element 5G′, and the blue light-emitting element 5B′ are top-emitting light-emitting elements, the lower electrodes 22′ serving as cathodes provided in the non-emitting charge transfer elements 6R′, 6G′, and 6B′ illustrated in FIG. 10 may be formed of an electrode material that transmits visible light, and the second upper electrode layer 28a′ serving as an anode may be formed of an electrode material that transmits visible light or reflects visible light as long as the layer is a resistance adjustment layer having a resistivity higher than that of the first upper electrode layer 28′ and equal to or lower than 1×10⁹ Ω·cm.

In order to realize a display device having a top-emitting light-emitting element, although an example in which an Al film is used as the lower electrode 22′ as a cathode, an indium tin oxide (ITO) film that is a transparent metal oxide is used as the first upper electrode layer 28′ as an anode, and an indium zinc oxide (IZO) film that is a transparent metal oxide having a higher resistivity than the indium tin oxide (ITO) film is used as the second upper electrode layer 28a′ as an anode in the display device 1d of the present embodiment illustrated in FIG. 10, the disclosure is not limited thereto.

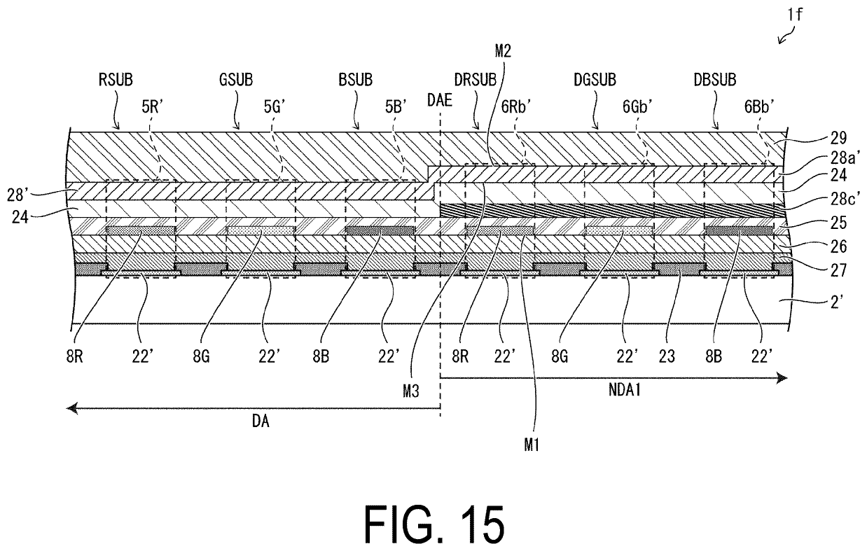

As an example of a case for the display device 1d of the present embodiment illustrated in FIG. 10, in which the non-emitting charge transfer elements 6R′, 6G′, and 6B′ includes a resistance adjustment layer between a first surface M1, which is the surface of the charge transfer layer (electron transfer layer), for example, the electron transport layer 26 on the light-emitting layers 8R, 8G, and 8B side, and a second surface M2, which is the surface on the side opposite to the substrate 2′ of the second upper electrode layer 28a′, the resistance adjustment layer having a resistivity higher than that of the first upper electrode layer 28′ and equal to or lower than 1×10⁹ Ω·cm, an example in which the resistance adjustment layer which is electrically connected to the first upper electrode layer 28′ and the second upper electrode layer 28a′ and which is the second upper electrode layer 28a′ having a resistivity higher than that of the first upper electrode layer 28′ and equal to or lower than 1×10⁹ Ω·cm is described; however, the disclosure is not limited thereto. For example, as in a seventh embodiment to be described below (see FIG. 15), the non-emitting charge transfer elements may include a resistance adjustment layer 28c′ between the first surface M1 of the charge transfer layer (electron transfer layer), for example, the electron transport layer 26 on the light-emitting layers 8R, 8G, and 8B side and the third surface M3 of the second upper electrode layer 28a′ on the light-emitting layers 8R, 8G, and 8B side, the resistance adjustment layer having a resistivity higher than that of the first upper electrode layer 28′ and equal to or lower than 1×10⁹ Ω·cm.

As illustrated in FIG. 10, in the display device 1d, electronse having transferred from the display region DA to the non-display region NDA1 through at least one of the electron injection layer 27 or the electron transport layer 26 as charge transfer layers (electron transfer layers) are accumulated in the non-display region NDA1 having nowhere to go. According to the non-emitting charge transfer elements 6R′, 6G′ and 6B′ provided in the non-display region NDA1, since the second upper electrode layer 28a′ is provided as a resistance adjustment layer as described above, the holes H⁺ and the electrons e are prevented from recombining in the light-emitting layers 8R, 8G and 8B by lowering the voltage applied between the lower electrodes 22′ and the second upper electrode layer 28a′, and the electrons e are allowed to flow to the second upper electrode layer 28a′, and thus the electrons e accumulated in the non-display region NDA1 can be released. That is, in the non-emitting charge transfer elements 6R′, 6G′, and 6B′, the voltage applied between the lower electrodes 22′ and the second upper electrode layer 28a′ is smaller than the energy required for recombining the holes H⁺ and the electrons e in the light-emitting layers 8R, 8G, and 8B, so light emission can be minimized and the electrons e can flow to the second upper electrode layer 28a′. It is possible to prevent the electrons e accumulated as described above from moving toward the second upper electrode layer 28a′ and accumulating in the non-display region NDA1, and to prevent a bright line from being generated in the non-display region NDA1.

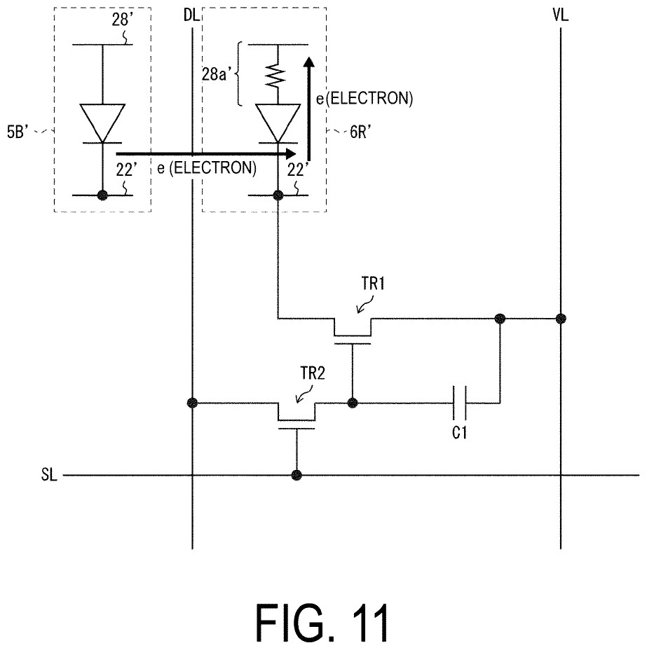

FIG. 11 is a circuit diagram illustrating a circuit near a boundary between the display region DA and the non-display region NDA1 of the display device 1d illustrated in FIG. 10.

FIG. 11 illustrates a schematic circuit configuration of a drive circuit of the blue subpixel BSUB including the blue light-emitting element 5B′ provided in the display region DA of the display device 1d and a drive circuit of the first dummy subpixel DRSUB including the non-emitting charge transfer element 6R′ provided in the non-display region NDA1 of the display device 1d adjacent to the blue light-emitting element 5B′. Note that the drive circuit of the blue subpixel BSUB including the blue light-emitting element 5B′ and the drive circuit of the first dummy subpixel DRSUB including the non-emitting charge transfer element 6R′ are provided on the substrate 2′ illustrated in FIG. 10. Note that, since the circuit configuration of the drive circuit of the blue subpixel BSUB including the blue light-emitting element 5B′ and the drive circuit of the first dummy subpixel DRSUB including the non-emitting charge transfer element 6R′ is described in the first embodiment, the description thereof is omitted here.

In the display device 1d illustrated in FIGS. 10 and 11 in which the electron injection layer 27 and the electron transport layer 26 are provided as a charge transfer layer (electron transfer layer) in the display region DA and the non-display region NDA1, since the non-emitting charge transfer elements 6R′, 6G′, and 6B′ are provided in the non-display region NDA1 of the display device 1d as described above, it is possible to minimize the occurrence of bright lines in the end portion area of the display region DA provided near the non-display region NDA1 of the display device 1d.

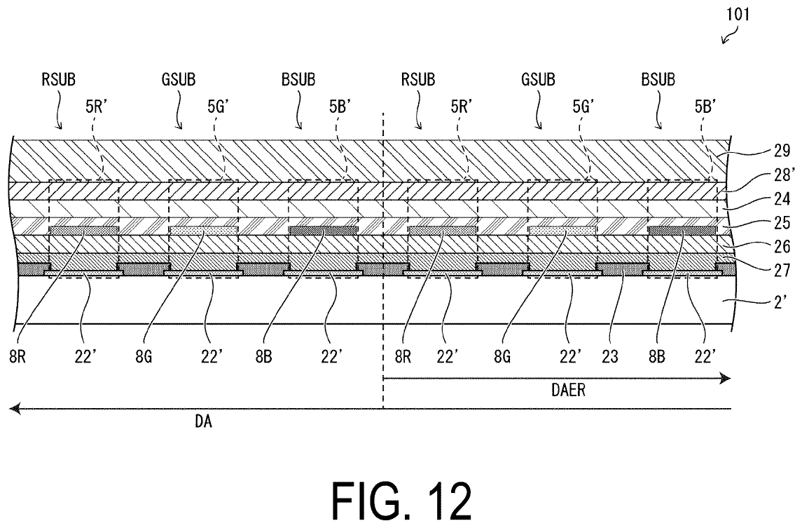

FIG. 12 is a cross-sectional view illustrating a schematic configuration of a display device 101 according to a comparative example in which the red light-emitting element 5R′, the green light-emitting element 5G′, and the blue light-emitting element 5B′ provided in an end portion area DAER of the display region DA emit light with luminance higher than intended, causing bright lines to appear.

As illustrated in FIG. 12, the red subpixel RSUB provided in the display region DA including the end portion area DAER of the display region DA in the display device 101 includes the red light-emitting element 5R′ including the red light-emitting layer 8R, the green subpixel GSUB provided in the display region DA including the end portion area DAER of the display region DA in the display device 101 includes the green light-emitting element 5G′ including the green light-emitting layer 8G, and the blue subpixel BSUB provided in the display region DA including the end portion area DAER of the display region DA in the display device 101 includes the blue light-emitting element 5B′ including the blue light-emitting layer 8B.

The electron injection layer 27 and the electron transport layer 26 are provided as a charge transfer layer (electron transfer layer) which is a common layer formed over the entire surface of the display region DA between the lower electrode 22′ and the red light-emitting layer 8R provided in the red light-emitting element 5R′, between the lower electrode 22′ and the green light-emitting layer 8G provided in the green light-emitting element 5G′, and between the lower electrode 22′ and the blue light-emitting layer 8B provided in the blue light-emitting element 5B′ of the display device 101 according to the comparative example illustrated in FIG. 12.

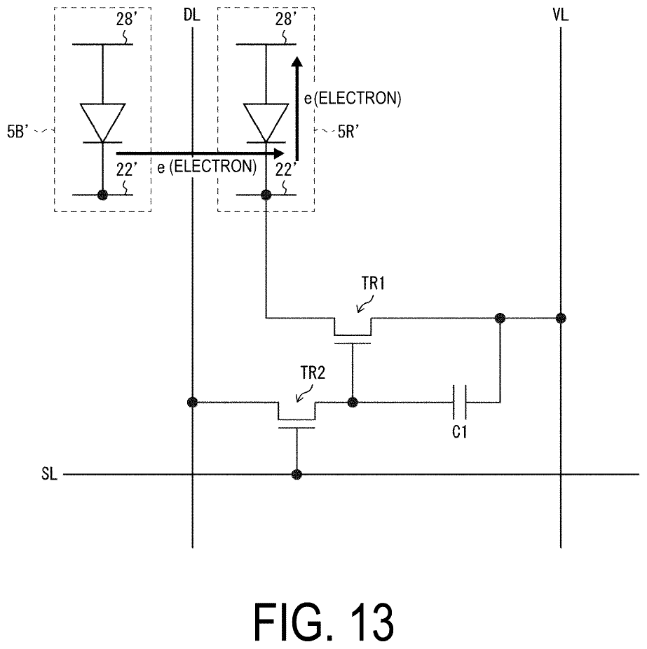

FIG. 13 is a circuit diagram for explaining the reason that a bright line appears in the end portion area DAER of the display region DA of the display device 101 according to the comparative example illustrated in FIG. 12. FIG. 13 illustrates a schematic circuit configuration of the drive circuit of the red subpixel RSUB including the red light-emitting element 5R′ provided in the end portion area DAER of the display region DA in the display device 101 according to the comparative example illustrated in FIG. 12, and the blue light-emitting element 5B′ disposed adjacent to the red light-emitting element 5R′. Note that, since the circuit configuration illustrated in FIG. 13 is described above in the first embodiment, the description thereof is omitted here.

In the display device 101 according to the comparative example illustrated in FIG. 12, in which the electron injection layer 27 and the electron transport layer 26 are provided as a charge transfer layer (electron transfer layer) which is a common layer formed over the entire surface of the display region DA, a bright line appears in the end portion area DAER of the display region DA. The inventors of the disclosure consider that one of the reasons for the occurrence of the above-mentioned bright line is as follows. As illustrated in FIGS. 12 and 13, the electrons e having transferred to the end portion area DAER of the display region DA through the electron injection layer 27 and electron transport layer 26 as the charge transfer layer (electron transfer layer) are accumulated in the end portion area DAER of the display region DA having nowhere to go, then, in the light-emitting element provided in the end portion area DAER of the display region DA, the electrons e accumulated as discussed above transfer toward the first upper electrode layer 28′, and light is emitted with luminance higher than intended. In the display device 101 according to the comparative example, a case has been described as an example in which the electron injection layer 27 and the electron transport layer 26 are provided as the charge transfer layer (electron transfer layer) which is a common layer formed over the entire surface of the display region DA. However, without being limited thereto, in a case where only one of the electron injection layer 27 and the electron transport layer 26 is provided, a bright line also appears similarly in the end portion area DAER of the display region DA.

### Sixth Embodiment

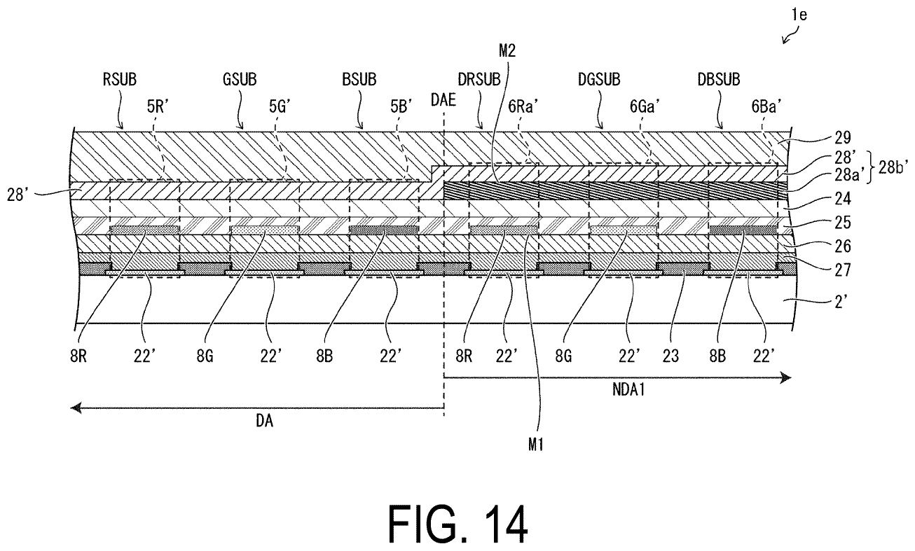

Next, a sixth embodiment of the disclosure will be described with reference to FIG. 14. A display device 1e of the present embodiment is different from that of the fifth embodiment in that the first upper electrode layer 28′ is also provided in the non-display region NDA1 as one continuous layer, and the second upper electrode layer 28a′ and the first upper electrode layer 28′ are layered in this order from the substrate 2′ side in the non-display region NDA1. The other details are as described in the fifth embodiment. For convenience of description, members having the same functions as those shown in the drawings according to the fifth embodiment are denoted by the same reference numerals and signs, and descriptions thereof will be omitted.

FIG. 14 is a cross-sectional view illustrating a schematic configuration of a red light-emitting element 5R′, a green light-emitting element 5G′, and a blue light-emitting element 5B′ provided in the display region DA, and a non-emitting charge transfer element 6Ra′ including a red light-emitting layer 8R, a non-emitting charge transfer element 6Ga′ including a green light-emitting layer 8G, and a non-emitting charge transfer element 6Ba′ including a blue light-emitting layer 8B provided in the non-display region NDA1 of the display device 1e according to the sixth embodiment.

As illustrated in FIG. 14, in each of the non-emitting charge transfer element 6Ra′ including the red light-emitting layer 8R, the non-emitting charge transfer element 6Ga′ including the green light-emitting layer 8G, and the non-emitting charge transfer element 6Ba′ including the blue light-emitting layer 8B provided in the non-display region NDA1 of the display device 1e, the first upper electrode layer 28′ is also provided as one continuous layer in the non-display region NDA1, and the second upper electrode layer 28a′ and the first upper electrode layer 28′ are layered in this order from the substrate 2′ side to form a layered body 28b′ in the non-display region NDA1. In such a case, the layered body 28b′ serves as an anode.

In the non-emitting charge transfer elements 6Ra′, 6Ga′ and 6Ba′ provided in the non-display region NDA1, since the second upper electrode layer 28a′ is provided as a resistance adjustment layer having a resistivity higher than that of the first upper electrode layer 28′ and equal to or lower than 1×10⁹ Ω·cm, the holes H⁺ and the electrons e are prevented from recombining in the light-emitting layers 8R, 8G and 8B by lowering the voltage applied between the lower electrodes 22′ and the layered body 28b′ serving as an anode, and the electrons e are allowed to flow to the layered body 28b′ serving as an anode, and thus the electrons e accumulated in the non-display region NDA1 can be released. It is possible to prevent the electrons e accumulated as described above from moving toward the layered body 28b′ serving as an anode and accumulating in the non-display region NDA1, and to prevent a bright line from being generated in the non-display region NDA1.

### Seventh Embodiment

Next, a seventh embodiment of the disclosure will be described with reference to FIG. 15. A display device If of the present embodiment is different from those of the above-described fifth and sixth embodiments in that the first upper electrode layer 28′ and the second upper electrode layer 28a′ are one continuous layer made of the same material, and the resistance adjustment layer 28c′ having a resistivity higher than that of the first upper electrode layer 28′ and equal to or lower than 1×10⁹ Ω·cm is provided between the first surface M1 of the electron transport layer 26 serving as a charge transfer layer (electron transfer layer) on the light-emitting layers 8R, 8G and 8B side and the third surface M3 of the second upper electrode layer 28a′ on the light-emitting layers 8R, 8G and 8B side. The other details are as described in the fifth and sixth embodiments. For convenience of description, members having the same functions as those of the members illustrated in the drawings in the fifth and sixth embodiments are denoted by the same reference numerals, and descriptions thereof will be omitted.

FIG. 15 is a cross-sectional view illustrating a schematic configuration of a red light-emitting element 5R′, a green light-emitting element 5G′ and a blue light-emitting element 5B′ provided in the display region DA, and a non-emitting charge transfer element 6Rb′ including a red light-emitting layer 8R, a non-emitting charge transfer element 6Gb′ including a green light-emitting layer 8G, and a non-emitting charge transfer element 6Bb′ including a blue light-emitting layer 8B provided in the non-display region NDA1 of the display device If according to the seventh embodiment.

As illustrated in FIG. 15, in each of the non-emitting charge transfer element 6Rb′ including the red light-emitting layer 8R, the non-emitting charge transfer element 6Gb′ including the green light-emitting layer 8G, and the non-emitting charge transfer element 6Bb′ including the blue light-emitting layer 8B provided in the non-display region NDA1 of the display device 1f, the first upper electrode layer 28′ and the second upper electrode layer 28a′ are a continuous layer made of the same material, and the resistance adjustment layer 28c′ having a resistivity higher than that of the first upper electrode layer 28′ and equal to or lower than 1×10⁹ Ω·cm is provided between the first surface M1 of the electron transport layer 26 serving as a charge transfer layer (electron transfer layer) on the light-emitting layers 8R, 8G, and 8B side and the third surface M3 of the second upper electrode layer 28a′ on the light-emitting layers 8R, 8G, and 8B side.

Although a case in which the resistance adjustment layer 28c′ is provided between the hole transport layer 25 and the hole injection layer 24 is described as an example in the present embodiment, the disclosure is not limited thereto. For example, the resistance adjustment layer 28c′ may be provided between the second upper electrode layer 28a′ and the hole injection layer 24, between the hole transport layer 25 and the light-emitting layers 8R, 8G, and 8B, or between the light-emitting layers 8R, 8G, and 8B and the electron transport layer 26, or may be provided at a plurality of the above-described positions.

In the non-emitting charge transfer elements 6Rb′, 6Gb′ and 6Bb′ provided in the non-display region NDA1, since the resistance adjustment layer 28c′ is provided between the first surface M1 of the electron transport layer 26 serving as a charge transfer layer (electron transfer layer) on the light-emitting layers 8R, 8G, and 8B side and the third surface M3 of the second upper electrode layer 28a′ on the light-emitting layers 8R, 8G, and 8B side, the holes H⁺ and the electrons e are prevented from recombining in the light-emitting layers 8R, 8G and 8B by lowering the voltage applied between the lower electrodes 22′ and the second upper electrode layer 28a′ serving as an anode, and the electrons e are allowed to flow to the second upper electrode layer 28a′ serving as an anode, and thus the electrons e accumulated in the non-display region NDA1 can be released. It is possible to prevent the electrons e accumulated as described above from moving toward the second upper electrode layer 28a′ serving as an anode and accumulating in the non-display region NDA1, and to prevent a bright line from being generated in the non-display region NDA1.

### Eighth Embodiment

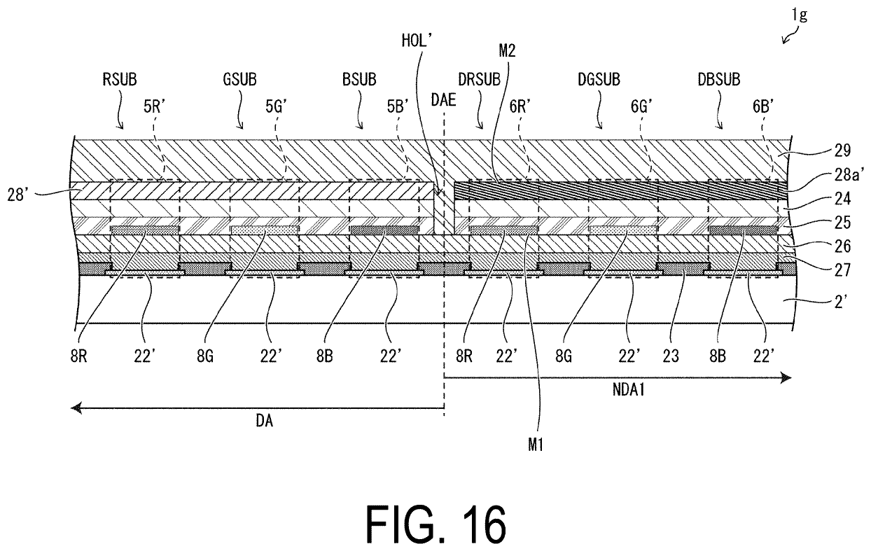

Next, an eighth embodiment of the disclosure will be described with reference to FIG. 16. A display device 1g of the present embodiment is different from those of the fifth to seventh embodiments in that the first upper electrode layer 28′ and the second upper electrode layer 28a′ are electrically separated from each other, the second upper electrode layer 28a′ is a resistance adjustment layer having a resistivity higher than that of the first upper electrode layer 28′ and equal to or lower than 1×10⁹ Ω·cm, a first voltage is applied to the first upper electrode layer 28′ via a first wiring line, a second voltage is applied to the second upper electrode layer 28a′ via a second wiring line, and the first voltage and the second voltage are the same. The other details are as described in the fifth to seventh embodiments. For convenience of description, members having the same functions as those illustrated in the drawings according to the fifth to seventh embodiments are denoted by the same reference numerals and signs, and descriptions thereof will be omitted.

FIG. 16 is a cross-sectional view illustrating a schematic configuration of a red light-emitting element 5R′, a green light-emitting element 5G′ and a blue light-emitting element 5B′ provided in the display region DA, and a non-emitting charge transfer element 6R′ including a red light-emitting layer 8R, a non-emitting charge transfer element 6G′ including a green light-emitting layer 8G, and a non-emitting charge transfer element 6B′ including a blue light-emitting layer 8B provided in the non-display region NDA1 of the display device 1g according to the eighth embodiment.

As illustrated in FIG. 16, in the display device 1g, a groove HOL′ for electrically separating the first upper electrode layer 28′ and the second upper electrode layer 28a′ is provided in an area including an end portion DAE of the display region DA, and the first upper electrode layer 28′ and the second upper electrode layer 28a′ are electrically separated from each other.

Although a case in which the groove HOL′ is also provided in the hole transport layer 25 and the hole injection layer 24 is described as an example in the present embodiment, the disclosure is not limited thereto, and the groove HOL′ may be provided only between the first upper electrode layer 28′ and the second upper electrode layer 28a′.

As illustrated in FIG. 16, in the display device 1g, the first upper electrode layer 28′ and the second upper electrode layer 28a′ are electrically separated from each other, the second upper electrode layer 28a′ is a resistance adjustment layer having a resistivity higher than that of the first upper electrode layer 28′ and equal to or lower than 1×10⁹ Ω·cm, the first voltage is applied to the first upper electrode layer 28′ via the first wiring line, the second voltage is applied to the second upper electrode layer 28a′ via the second wiring line, and the first voltage and the second voltage are the same.

In the display device 1g, the red light-emitting element 5R′, the green light-emitting element 5G′, and the blue light-emitting element 5B′ provided in the display region DA can be prevented from being affected by the non-emitting charge transfer elements 6R′, 6G′, and 6B′ provided in the non-display region NDA1.

### Ninth Embodiment

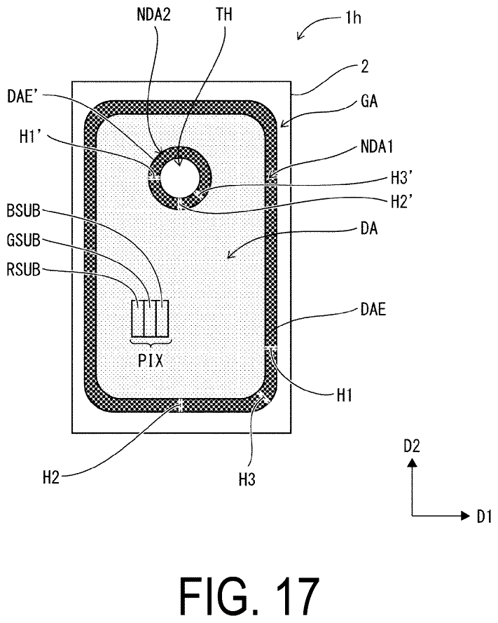

Next, a ninth embodiment of the disclosure will be described with reference to FIG. 17. A display device 1h of the present embodiment is different from those of the above-described first to eighth embodiments in that an imaging region TH configured to transmit imaging light is further provided inward from the display region DA, and a non-display region (first non-display region) NDA1 provided to surround the outer perimeter of the display region DA and a non-display region (second non-display region) NDA2 provided to surround the imaging region TH are included. The other details are as described in the first and second embodiments. For convenience of description, members having the same functions as those shown in the drawings according to the first and second embodiments are denoted by the same reference numerals and signs, and descriptions thereof will be omitted.

FIG. 17 is a plan view illustrating a schematic configuration of the display device 1h according to the ninth embodiment.

As illustrated in FIG. 17, the display device 1h further includes the imaging region TH configured to transmit imaging light inward from the display region DA, and the non-display region (first non-display region) NDA1 provided to surround the outer perimeter of the display region DA and the non-display region (second non-display region) NDA2 provided to surround the imaging region TH are included. The imaging region TH configured to transmit imaging light may be a through hole passing through from the front face to the back face of the display device 1h, or may be a region formed of only a transparent material to transmit the imaging light. Note that the imaging light is light reflected from a subject and necessary for imaging by an imaging element (not illustrated) arranged to overlap the imaging region TH of the display device 1h in a plan view and disposed at the back face side of the display device 1h.

Each of the non-display region NDA1 and the non-display region NDA2 of the display device 1h may have the same configuration as the non-display region NDA1 described above in the first embodiment or may have the same configuration as the non-display region NDA1 described above in the fifth embodiment.

Note that, although a case is described as an example in which the imaging region TH is formed in a circular shape and the non-display region NDA2 is also formed in a circular shape in the present embodiment, the shapes thereof are not limited thereto, and for example, the imaging region TH may be formed in a rectangular shape and the non-display region NDA2 may also be formed in a rectangular shape.

As illustrated in FIG. 17, since the non-display region NDA2 is a region where no display is performed, it is preferable that the non-display region NDA2 be provided to have a width not greater than necessary. Accordingly, when the shape of a pixel PIX is rectangular as in the present embodiment, it is preferable that the non-display region NDA2 be formed having a width equal to or less than the length of a diagonal line of the pixel PIX. Although a case is described as an example in which widths H1′, H2′, and H3′ of the non-display region NDA2 are each formed to take a width in a first direction D1 of the pixel PIX in order to make the widths H1′, H2′, and H3′ of the non-display region NDA2 equal to or less than the length of the diagonal line of the pixel PIX in the present embodiment, the disclosure is not limited thereto, and the widths H1′, H2′, and H3′ of the non-display region NDA2 may be each formed to take a width in a second direction D2 of the pixel PIX or a width equal to the length of the diagonal line of the pixel PIX. In addition, for example, the widths H1′, H2′, and H3′ of the non-display region NDA2 may be formed to be 50 μm or less, or are preferably formed to be 5 μm or more and 50 μm or less. By setting the widths of the non-display region NDA2 to be in the above-described range, it is possible to achieve the display device 1h capable of obtaining a wider display region DA for the display device 1h and configured to prevent the light-emitting element provided in an end portion DAE′ area of the display region DA from emitting light with luminance higher than intended, causing bright lines to appear.

### APPENDIX

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in the embodiments.

### INDUSTRIAL APPLICABILITY

The disclosure can be utilized for a display device.

1. A display device comprising:
a substrate;
a display region located on the substrate and provided with a plurality of pixels, each pixel including a plurality of subpixels;
a non-display region located on the substrate, the non-display region including a plurality of dummy subpixels provided along an end portion of the display region, the non-display region being continuous from the display region;
a plurality of lower electrodes provided in each of the display region and the non-display region;
a charge transfer layer which is one continuous layer provided across the display region and the non-display region;
a first upper electrode layer provided in the display region;
a second upper electrode layer provided in the non-display region;
a light-emitting element provided in each of the plurality of subpixels and including each of the plurality of lower electrodes, the charge transfer layer, a light-emitting layer, and the first upper electrode layer in this order from the substrate side; and
a non-emitting charge transfer element provided in each of the plurality of dummy subpixels and including each of the plurality of lower electrodes, the charge transfer layer, a light-emitting layer, and the second upper electrode layer in this order from the substrate side,
wherein the non-emitting charge transfer element includes a resistance adjustment layer between a first surface that is a surface of the charge transfer layer on the light-emitting layer side and a second surface of the second upper electrode layer that is the surface on a side opposite to the substrate, the resistance adjustment layer having a resistivity higher than a resistivity of the first upper electrode layer and equal to or lower than 1×10⁹ Ω·cm.

2. The display device according to claim 1,
wherein the first upper electrode layer and the second upper electrode layer are electrically connected to each other, and
the resistance adjustment layer is the second upper electrode layer.

3. The display device according to claim 2,
wherein the first upper electrode layer is also provided in the non-display region as one continuous layer, and
in the non-display region, the second upper electrode layer and the first upper electrode layer are layered in this order from the substrate side.

4. The display device according to claim 1,
wherein the first upper electrode layer and the second upper electrode layer are one continuous layer formed of the same material, and
the resistance adjustment layer is provided between the first surface and a third surface of the second upper electrode layer, the third surface being a surface on the light-emitting layer side.

5. The display device according to claim 1,
wherein the first upper electrode layer and the second upper electrode layer are electrically separated from each other,
the resistance adjustment layer is the second upper electrode layer,
a first voltage is applied to the first upper electrode layer via a first wiring line,
a second voltage is applied to the second upper electrode layer via a second wiring line, and the first voltage and the second voltage are the same voltage.

6. The display device according to claim 1,
wherein each of the plurality of lower electrodes is an anode,
each of the first upper electrode layer and the second upper electrode layer is a cathode, and
the charge transfer layer is at least one of a hole injection layer or a hole transport layer.

7. The display device according to claim 6,
wherein at least one of an electron injection layer or an electron transport layer is provided between the light-emitting layer and the first upper electrode layer in the display region and between the light-emitting layer and the second upper electrode layer in the non-display region.

8. The display device according to claim 1,
wherein each of the plurality of lower electrodes is a cathode,
each of the first upper electrode layer and the second upper electrode layer is an anode, and
the charge transfer layer is at least one of an electron injection layer or an electron transport layer.

9. The display device according to claim 8,
wherein at least one of a hole injection layer or a hole transport layer is provided between the light-emitting layer and the first upper electrode layer in the display region and between the light-emitting layer and the second upper electrode layer in the non-display region.

10. The display device according to claim 1,
wherein the non-display region is provided to surround the display region.

11. The display device according to claim 1,
wherein the non-display region includes a first non-display region and a second non-display region,
an imaging region configured to transmit imaging light is provided inward from the display region,
the first non-display region is provided to surround an outer perimeter of the display region, and
the second non-display region is provided to surround the imaging region.
